(19) United States
(12) Patent Application Publication
(10) Pub. No.: US 2010/0289103 A1
(43) Pub. Date: Nov. 18, 2010

(54) PIN Photodiode and Light Reception Device

(75) Inventors: Masashi Yamamoto, Kyoto-fu (JP); Jun Ichihara, Kyoto-fu (JP)

Correspondence Address: RABIN & Berdo, PC, 1101 14TH STREET, NW, SUITE 500, WASHINGTON, DC, 20005, US

(73) Assignee: ROHM CO., LTD., KYOTO-FU (JP)

(21) Appl. No.: 12/086,480

(22) PCT Filed: Dec. 13, 2006
(86) PCT No.: PCT/JP2006/324822

§ 371 Date: Jul. 8, 2010

(30) Foreign Application Priority Data
Dec. 14, 2005 (JP) 2005360922

(51) Int. Cl. H01L 31/105

(52) U.S. Cl. 257/458; 257/466; 257/E31.061; 257/E31.032

(57) ABSTRACT

Among photodiodes used in an optical system for applying light to the entire chip, the conventional PIN photodiode has a problem that light should be applied only to a light reception surface in order to prevent degradation of light response and that positioning of the optical system is difficult. Moreover, in the mesa type PIN photodiode not requiring positioning of an optical system, disconnection failure is often caused by the mesa step. The present invention is made to solve the aforementioned problems, and its object is to provide a PIN photodiode having an improved light response and causing less disconnection failure of metal wiring and a light reception device using the PIN photodiode. The PIN photodiode of the present invention has a structure that the light reception surface is surrounded by a groove of a predetermined depth.

### TECHNICAL FIELD

The present invention relates to a PIN photodiode having an improved light response and a light reception device using the PIN photodiode.

BACKGROUND ART

A light pick-up device for a CD, DVD, or MD, which device applies a laser beam to a disc-shaped recording medium to read information recorded thereon, includes a photodiode to receive light reflected by the recording medium and convert the received light into an electrical signal. Moreover, a photodiode is also provided to a reception device used for optical communications through the Internet and the like, which reception device has become widespread in recent years. A photodiode has been desired to have a fast response because a lot of information such as music and moving images needs to be received in a short time period.

As a photodiode suitable for a fast response, there is a PIN photodiode having a structure in which an intrinsic semiconductor layer with few carriers is interposed between a p-type semiconductor layer and an n-type semiconductor layer (for example, see Patent Document 1). A PIN photodiode is used by applying a reverse bias voltage V_{cc} thereto, as shown in FIG. 6. In FIG. 6, Reference Numeral 301 denotes a PIN photodiode. An electric field is generated in the intrinsic semiconductor layer by a reverse bias voltage V_{cc}; electrons and holes generated, by incident light 66, in the intrinsic semiconductor layer easily move according to the electric field. Here, the holes move to the p-type semiconductor layer, whereas the electrons move to the n-type semiconductor layer. An electrical current i caused by movement of electrons and holes flows through a resistance R, so that a voltage is generated to be outputted as an output voltage Vₒᵤₜ. A larger film thickness of an intrinsic semiconductor layer of a PIN photodiode causes a higher absorption amount of light becomes larger, thereby making it possible to obtain high efficiency. In addition, a lower carrier density of an intrinsic semiconductor layer allows a depletion layer to be easily extended even with a low voltage. A larger width of a depletion layer reduces a junction capacitance, thereby making it possible to obtain a fast response.

In general, a PIN photodiode has a structure in which an n-type semiconductor layer, an intrinsic semiconductor layer and a p-type semiconductor layer are laminated in this order, and light is incident on a surface, opposite to the intrinsic semiconductor layer, of the p-type semiconductor layer (hereinafter, “the surface, opposite to the intrinsic semiconductor layer, of the p-type semiconductor layer” is simply referred to as “a light-reception-side surface”).

Hereinbelow, a description will be given on the assumption that: a stacking direction of semiconductor layers is a vertical direction of the PIN photodiode; a direction perpendicular to the stacking direction of the semiconductor layers is a horizontal direction; and in the vertical direction, a direction from the n-type semiconductor layer to the p-type semiconductor layer is an upward direction.

### Patent Document 1: Japanese Patent Application Publication No. 2005-216874

### DISCLOSURE OF THE INVENTION

### Problems To Be Solved By the Invention

The conventional PIN photodiode generates electrons and holes from the entire intrinsic semiconductor layer on which light from the light-reception-side surface is incident. Moreover, in the PIN photodiode, a p-side electrode is disposed to be in contact with a part of the p-type semiconductor layer, while the holes move toward the p-side electrode in the horizontal direction through the intrinsic semiconductor layer and the p-type semiconductor layer. Even with a simultaneously irradiated light, moving distance of holes to the p-side electrode varies depending on the positions where the holes are generated. For this reason, the time needed for the holes to reach the p-side electrode varies. Accordingly, a certain amount of time is needed for an output voltage of the PIN photodiode to be in a steady state from the time when light is started to be applied, or for an output voltage of the PIN photodiode to become zero from the time when light is blocked. As a result, in the conventional PIN photodiode, a delay in response of an output voltage to an input light signal (degradation of light response) is caused.

An eye pattern indicating light response of the conventional PIN photodiode is shown in FIG. 8. As in the above description, a delay in response to an input light signal degrades a falling edge of an eye pattern (causes tailing). Improvement of the eye pattern is necessary for a light reception device in which a fast response is required.

There are mainly two means for improvement of an eye pattern. One is improvement in a light reception device using a PIN photodiode; the other is improvement in a PIN photodiode itself.

In the means of improving a light reception device, which is one of the improvement means, an optical system having lenses and the like combined for collecting light on a light reception surface is disposed on a light reception surface side of a PIN photodiode. Because light is applied only to the light reception surface, the number of electrons and holes generated in an intrinsic layer except below the light reception surface is very small compared with electric power outputted to the outside. Accordingly, an eye pattern can be improved. However, the optical system needs highly accurate positioning for applying light to the light reception surface, thereby making it difficult to assemble the light reception device.

Meanwhile, in the means of improving a PIN photodiode itself, which is the other one of the improvement means, a mesa is formed from a p-type semiconductor layer to an intrinsic semiconductor layer. Since an intrinsic semiconductor layer other than the mesa is removed, even when light is applied to the places other than the mesa, electrons and holes cannot move to a p-side electrode, thereby not being detected as an electric current. However, the mesa has a large step. In general, a PIN photodiode includes an electrode pad to facilitate an electrical connection to the outside, and the p-side electrode and the electrode pad is connected by metal wiring. The step of the mesa makes it difficult to dispose metal wiring that electrically connects the p-side electrode to the electrode pad, and also has a risk of causing disconnection failure.

The present invention has been made to solve the above-mentioned problem, and has an object to provide a PIN photodiode having an improved light response and causing less disconnection failure of metal wiring, and a light reception device using the PIN photodiode.

### Means For Solving the Problems

In order to achieve the above object, a PIN photodiode according to the present invention has a structure in which a light reception surface is surrounded by a groove of a predetermined depth.

To be specific, the present invention is a PIN photodiode comprising: an intrinsic semiconductor layer which generates, above a substrate, electrons and holes by incidence of light; an n-type semiconductor layer being formed on the intrinsic semiconductor layer on the substrate side in the stacking direction, and absorbing electrons generated in the intrinsic semiconductor layer; a p-type semiconductor layer being formed on the intrinsic semiconductor layer on the side opposite to the substrate in the stacking direction, and absorbing holes generated in the intrinsic semiconductor layer; and a first groove curving in the longitudinal direction so as to surround a certain area of a surface opposite to the substrate, and extending from the surface opposite to the substrate to have a depth deeper than the intrinsic semiconductor layer in the stacking direction.

The PIN photodiode has the first groove that surrounds a certain area of a surface, as a light reception surface, opposite to the substrate. Holes generated by incident light on the intrinsic semiconductor layer except the light reception surface cannot move to the intrinsic semiconductor layer below the light reception surface, because the groove functions as a barrier. Hence, if a p-side electrode being in contact with the light reception surface is provided, almost all holes reaching the p-side electrode are those generated in the intrinsic semiconductor layer below the light reception surface.

Moreover, a part of the first groove is blocked. If metal wiring is provided to extend through the part where the first groove is blocked so as to be connected with the p-side electrode, then there is no step between the blocked part of the first groove and a light-reception-side surface except the light reception surface. Thus, disconnection of the metal wiring is reduced.

Accordingly, the present invention can provide a PIN photodiode having an improved light response and causing less disconnection failure of metal wiring.

A PIN photodiode according to the present invention further comprises: an electrode pad being formed at a position different from the certain area surrounded by the first groove on the surface opposite to the substrate; and a second groove curving in the longitudinal direction so as to surround a part of an outer circumference of the electrode pad on the surface opposite to the substrate, and extending from the surface opposite to the substrate to have a depth deeper than the intrinsic semiconductor layer in the stacking direction.

The PIN photodiode further comprising the electrode pad and the second groove can obtain the same effect as the PIN photodiode comprising the first groove.

Assume that holes generated by incident light on the intrinsic semiconductor layer except the light reception surface reach the electrode pad by horizontally moving through the intrinsic semiconductor layer and the p-type semiconductor layer. Then a delay in response of an output voltage is caused, as described in “Problems to be Solved by the Invention.” If the second groove functioning as a barrier against movement of the holes is provided to surround a part of an outer circumference of the electrode pad, then the holes hardly reach the electrode pad.

Moreover, a part of the second groove is blocked. If metal wiring is provided to extend through the part where the second groove is blocked so as to be connected with the electrode pad, then there is no step between the blocked part of the second groove and a light-reception-side surface except the light reception surface. Thus, disconnection of the metal wiring is reduced.

Accordingly, the present invention can provide a PIN photodiode having an improved light response and causing less disconnection failure of metal wiring.

A PIN photodiode according to the present invention further comprises: a p-side electrode being formed on the surface, opposite to the substrate, of the p-type semiconductor layer in the certain area surrounded by the first groove, and being shaped so as to expose a part of the certain area surrounded by the first groove on the surface opposite to the substrate; metal wiring being formed on the surface opposite to the substrate so as to extend from an area where one end in the longitudinal direction of the first groove faces its other end to an area where one end in the longitudinal direction of the second groove faces its other end, and electrically connecting the p-side electrode to the electrode pad; a third groove extending, on the surface opposite to the substrate, from one end in the longitudinal direction of the first groove to one end in the longitudinal direction of the second groove, along one edge in the longitudinal direction of the metal wiring, and extending from the surface opposite to the substrate to have a depth deeper than the intrinsic semiconductor layer in the stacking direction; and a fourth groove extending, on the surface opposite to the substrate, from the other end in the longitudinal direction of the first groove to the other end in the longitudinal direction of the second groove, along the other edge in the longitudinal direction of the metal wiring, and extending from the surface opposite to the substrate to have a depth deeper than the intrinsic semiconductor layer in the stacking direction.

The PIN photodiode further comprising the a p-side electrode, the metal wiring, the third groove, and the fourth groove can obtain the same effect as the PIN photodiode comprising the first groove and the second groove.

Assume that holes generated by incident light on the intrinsic semiconductor layer except the light reception surface reach the metal wiring by horizontally moving through the intrinsic semiconductor layer and the p-type semiconductor layer. Then a delay in response of an output voltage is caused, as described in “Problems to be Solved by the Invention.” If the third groove and the fourth groove functioning as a barrier against movement of the holes are provided at both edges of the metal wiring, then the holes cannot reach the metal wiring.

In addition, if the first to the fourth grooves surround circumferences of the light reception surface, the electrode pad, and the metal wiring, then portions of the p-type semiconductor layer and the intrinsic semiconductor layer below the light reception surface, the electrode pad, and the metal wiring are completely independent of portions of the p-type semiconductor layer and the intrinsic semiconductor layer not below the light reception surface, the electrode pad, and the metal wiring. Thus, holes reaching the p-side electrode are only those generated in the intrinsic semiconductor layer below the light reception surface.

Moreover, in the PIN photodiode, the metal wiring is provided to extend from a portion where the first groove is blocked to a portion where the second groove is blocked, thereby connecting the p-side electrode to the electrode pad. Here, there is no step: between the light reception surface and the blocked part of the first groove; between the blocked part of the first groove and a light-reception-side surface except the light reception surface; and between the blocked part of the second groove and a light-reception-side surface except the light reception surface. Thus, disconnection of the metal wiring is reduced.

Accordingly, the present invention can provide a PIN photodiode having an improved light response and causing less disconnection failure of metal wiring.

A PIN photodiode according to the present invention comprises a first mesa portion, a second mesa portion, a third mesa portion. The first mesa portion includes: an intrinsic semiconductor layer above a substrate; an n-type semiconductor layer formed on the intrinsic semiconductor layer on the substrate side in the stacking direction; and a p-type semiconductor layer formed on the intrinsic semiconductor layer on the side opposite to the substrate in the stacking direction. The first mesa portion has a mesa extending from a surface, opposite to the substrate, of the p-type semiconductor layer to at least apart of the n-type semiconductor layer, and having, as its top surface, a certain area of the surface, opposite to the substrate, of the p-type semiconductor layer. The first mesa portion has the p-side electrode shaped to expose a part of the certain area of the p-type semiconductor layer, and generates electrons and holes in the intrinsic semiconductor layer by light incident from the certain area of the p-type semiconductor layer exposed from the p-side electrode. The second mesa portion includes: the intrinsic semiconductor layer; the n-type semiconductor layer; the p-type semiconductor layer; and an electrode pad formed on the p-type semiconductor layer on the side opposite to the substrate. The second mesa portion has a mesa extending in the stacking direction from the electrode pad to at least a part of the n-type semiconductor layer. The third mesa portion includes: the intrinsic semiconductor layer; the n-type semiconductor layer; the p-type semiconductor layer; and metal wiring formed on the p-type semiconductor layer on the side opposite to the substrate. The third mesa portion has a mesa extending in the stacking direction from the metal wiring to at least a part of the n-type semiconductor layer, and connects the first mesa portion to the second mesa portion. In the PIN photodiode, the metal wiring of the third mesa portion electrically connects the p-side electrode of the first mesa portion to the electrode pad of the second mesa portion.

The intrinsic semiconductor layer except the first to the third mesa portions of the PIN photodiode is separated by a groove. For this reason, even when light is applied to a portion except the first to the third mesa portions and thus holes are generated, the holes cannot reach the p-side electrode. In other words, holes reaching the p-side electrode are only those generated in the intrinsic semiconductor layer below the light reception surface.

Moreover, in the PIN photodiode, the first mesa portion is sequentially connected with the third mesa portion and the second mesa portion having the same height as the first mesa portion, and there is no step from the first mesa portion to the second mesa portion. Thus, disconnection of the metal wiring connecting the p-side electrode to the electrode pad is reduced.

Accordingly, the present invention can provide a PIN photodiode having an improved light response and causing less disconnection failure of metal wiring.

The present invention is a light reception device comprising: the PIN photodiode; and a diffuser which diffuses light from the outside and uniformly applies light to an area including the certain area on the surface opposite to the substrate of the PIN photodiode.

The PIN photodiode can maintain a fast response, even when light is applied to an area except the light reception surface. Accordingly, when the diffuser capable of uniformly applying light to the entire light-reception-side surface in a widespread manner is provided, it is possible to eliminate the need for an optical system requiring highly accurate positioning to apply light to the light reception surface.

Accordingly, the present invention can provide a light reception device in which highly accurate positioning is not required for applying light to the certain area of the PIN photodiode having an improved light response and causing less disconnection failure of metal wiring.

### Effects of the Invention

According to the present invention, it is possible to provide a PIN photodiode having an improved light response and causing less disconnection failure of metal wiring, and a light reception device using the PIN photodiode.

### BRIEF DESCRIPTION OF THE DRAWINGS

FIG. 1 is a conceptual diagram of a PIN photodiode 101 according to the present invention; (a) is a top view, seen from above, of the light reception surface side; and (b) is a diagram showing a cross section taken along the line A-A′.

FIG. 2 is a conceptual diagram of a PIN photodiode 102 according to the present invention; (a) is a top view, seen from above, of the light reception surface side; and (b) is a diagram showing a cross section taken along the line A-A′.

FIG. 3 is a conceptual diagram of a PIN photodiode 103 according to the present invention; (a) is a top view, seen from above, of the light reception surface side; and (b) is a diagram showing a cross section taken along the line A-A′.

FIG. 4 is a conceptual diagram of a PIN photodiode 104 according to the present invention; (a) is a top view, seen from above, of the light reception surface side; and (b) is a diagram showing a cross section taken along the line A-A′.

FIG. 5 is a conceptual diagram of a light reception device 901 according to the present invention.

FIG. 6 is a diagram showing an example of a connection circuit of a light reception device using the PIN photodiode.

FIG. 7 is an eye pattern showing light response of a PIN photodiode according to the present invention.

FIG. 8 is an eye pattern showing light response of the conventional PIN photodiode.

### DESCRIPTION OF REFERENCE NUMERALS

101, 102, 103, 104, 301 PIN Photodiode
901 Light reception device
3 P-Side Electrode
5 Light Reception Surface
7 Metal Wiring
9 Electrode Pad
10 First Groove
11 N-Side Electrode
12 Substrate
13 N-Type Semiconductor Layer
14 Intrinsic Semiconductor Layer
15 P-Type Semiconductor Layer
16 Insulating Film
17 Anti-Reflection Film
20 Second Groove
30 Third Groove
40 Fourth Groove
43 First Mesa Portion
45 Second Mesa Portion
47 Third Mesa Portion
51 Diffuser
51a Incoming Edge of Diffuser 51
51b Outgoing Edge of Diffuser 51
53 Outgoing Light
55 Incoming Light
66 Light

### BEST MODES FOR CARRYING OUT THE INVENTION

Hereinafter, embodiments of the present invention will be described in detail with reference to the drawings. It should be noted that the present invention is not limited to the embodiments shown below.

### First Embodiment

In this embodiment, provided is a PIN photodiode that includes: an intrinsic semiconductor layer; an n-type semiconductor layer; a p-type semiconductor layer; and a first groove. The intrinsic semiconductor layer generates, above a substrate, electrons and holes by incidence of light. The n-type semiconductor layer is formed on the intrinsic semiconductor layer on the substrate side in the stacking direction, and absorbs electrons generated in the intrinsic semiconductor layer. The p-type semiconductor layer is formed on the intrinsic semiconductor layer on the side opposite to the substrate in the stacking direction, and absorbs holes generated in the intrinsic semiconductor layer. The first groove curves in the longitudinal direction so as to surround a certain area of a surface opposite to the substrate, and extends from the surface opposite to the substrate to have a depth deeper than the intrinsic semiconductor layer in the stacking direction.

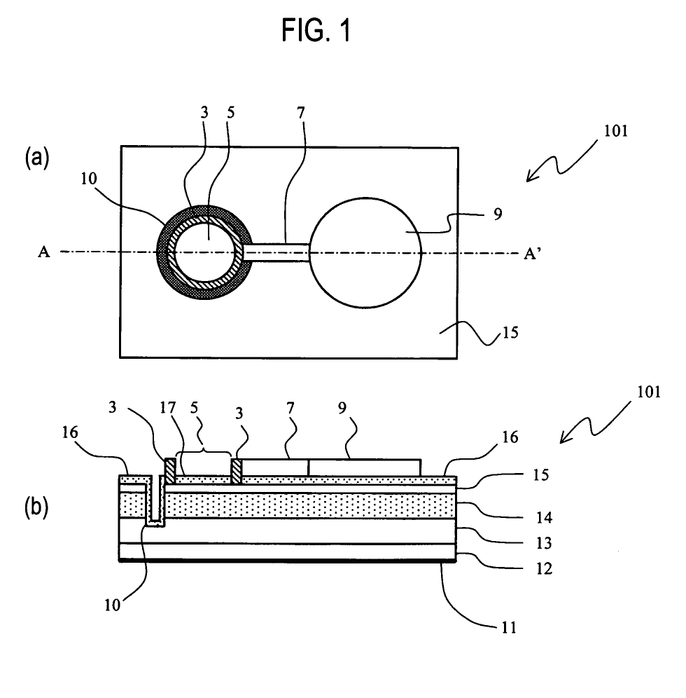

A conceptual diagram of a PIN photodiode 101 according to the present invention is shown in FIG. 1. FIG. 1(a) is a diagram seen from the light application direction of the PIN photodiode 101. FIG. 1(b) is a cross section taken along the line A-A′ of the PIN photodiode 101 in FIG. 1(a). The PIN photodiode 101 includes: an n-side electrode 11; a substrate 12; an n-type semiconductor layer 13; an intrinsic semiconductor layer 14; a p-type semiconductor layer 15; an insulating film 16; an anti-reflection film 17; a p-side electrode 3; a first groove 10; an electrode pad 9; and metal wiring 7. It should be noted that, in FIG. 1(a), illustrations of the insulating film 16 and the anti-reflection film 17 are omitted in order to describe a structure of the PIN photodiode 101.

The substrate 12 is disposed to physically support the PIN photodiode 101 including semiconductor thin films. A material for favorably growing semiconductor thin film is selected as the substrate of the PIN photodiode 101. For example, an n-type GaAs single crystal plate with a thickness of 200 μm in the stacking direction is exemplified.

The intrinsic semiconductor layer 14 is an intrinsic semiconductor layer that generates electrons and holes by the incidence of light. A wavelength of receivable light is determined depending on a band gap of the material adopted as the intrinsic semiconductor layer 14. For example, a GaAs compound semiconductor with a thickness of 3.5 μm in the stacking direction (hereinafter “a thickness in the stacking direction” will be simply referred to as “a film thickness”) can be exemplified as the intrinsic semiconductor layer 14. When a GaAs compound semiconductor is adopted for the intrinsic semiconductor layer 14, a wavelength of receivable light is from 400 nm to 780 nm.

The n-type semiconductor layer 13 is a semiconductor layer that absorbs electrons generated in the intrinsic semiconductor layer 14 and has an n-type polarity. For example, a GaAs compound semiconductor with a film thickness of not less than 10 nm to not more than 90 nm can be exemplified as the n-type semiconductor layer 13.

The p-type semiconductor layer 15 is a semiconductor layer that absorbs holes generated in the intrinsic semiconductor layer 14 and has a p-type polarity. For example, a GaAs compound semiconductor with a film thickness of not less than 10 nm to not more than 90 nm can be exemplified as the p-type semiconductor layer 15.

The first groove 10 is a groove having a width of not less than 0.01 mm to not more than 0.02 mm and extending from the surface (the insulating film 16) opposite to the substrate 12 to have a depth deeper than the intrinsic semiconductor layer 14 in the stacking direction. In addition, the first groove 10 curves in the longitudinal direction so as to surround a certain area of the light-reception-side surface. The certain area is a light reception surface 5 of the PIN photodiode 101. For example, the light reception surface 5 can be exemplified as a circle with a diameter of not less than 0.1 mm to not more than 0.15 mm.

The n-side electrode 11 and the p-side electrode 3 are disposed to apply a voltage to the PIN photodiode 101, and to extract photovoltaic power generated in the PIN photodiode 101. When rectification occurs due to a contact between an electrode and a semiconductor, the function of the PIN photodiode is impaired. For this reason, the n-side electrode 11 and the p-side electrode 3 are preferably materials that can have an ohmic contact with a semiconductor. For example, Ti/Au can be exemplified as the material for the n-side electrode 11 and the p-side electrode 3.

Incidentally, the p-side electrode 3 is shaped so as to expose a part of the light reception surface 5 surrounded by the first groove 10. A ring-shaped p-side electrode 3 is shown in the PIN photodiode 101 of FIG. 1. When a diameter of the light reception surface is 0.1 mm, it can be exemplified that a ring of the p-side electrode 3 has an outer diameter of 0.1 mm, an inner diameter of 0.08 mm, and a width of 0.01 mm. The shape of the p-side electrode 3 shown in FIG. 1 is an example. The p-side electrode 3 may have another shape as long as: light from the outside can be incident on the p-side electrode 3 in the certain area; a voltage can be applied to the p-type semiconductor layer 15; and holes can be absorbed from the p-type semiconductor layer 15.

The electrode pad 9 is connected with an outside device such as a power supply through electrical wiring. The electrode pad 9 is desirably a material having small contact resistance with the electrical wiring. For example, Ti/Au with a film thickness of 800 nm is exemplified as a material for the electrode pad 9. The shape of the electrode pad 9 can be exemplified as a circle with a diameter of 100 μm.

The metal wiring 7 electrically connects the electrode pad 9 with the p-side electrode 3, and transmits a voltage applied to the electrode pad 9 to the p-side electrode 3. For example, Ti/Au is exemplified as a material for the metal wiring 7. It can be exemplified that a line width of the metal wiring 7 is 0.02 mm.

The insulating film 16 is disposed between the p-type semiconductor layer 15 and the electrode pad 9 as well as between the p-type semiconductor layer 15 and the metal wiring 7, and provides electrical insulation so that holes cannot move from the p-type semiconductor layer 15 to the electrode pad 9 as well as to the metal wiring 7. For example, SiO₂ or SiN with a film thickness of not less than 100 nm to not more than 200 nm can be exemplified as the insulating film 16.

The PIN photodiode 101 is manufactured by a PIN photodiode manufacturing method as described below. The PIN photodiode manufacturing method sequentially performs: a semiconductor layer lamination process; a first insulating film formation process; a groove or mesa formation process; a second insulating film formation process; a back surface electrode formation process; and a p-side electrode formation process.

### Semiconductor Layer Lamination Process

The n-type semiconductor layer 13, the intrinsic semiconductor layer 14, and the p-type semiconductor layer 15 are sequentially stacked on the substrate 12 by the MOCVD method.

(First Insulating Film Formation Process)

SiN or SiO₂, serving as an insulating film, is stacked on the p-type semiconductor layer 15 stacked in the semiconductor layer lamination process, by the plasma CVD method.

(Groove Or Mesa Formation Process)

A resist is applied on the film of SiN or SiO₂ stacked in the first insulating film formation process, and a resist pattern is formed by the lithography method so as to have an opening corresponding to a portion to be etched. Subsequently, etching is performed by the dry etching method so that the portion corresponding to the opening of the resist is etched from the p-type semiconductor layer 15 to a predetermined depth. The p-type semiconductor layer 15 covered with the resist is not etched because it is protected. After the dry etching, a groove or a mesa is formed by removing the resist.

To be specific, in the PIN photodiode 101, an opening portion of the resist is the first groove 10; in a PIN photodiode 102, the first groove 10 and a second groove 20; in a PIN photodiode 103, the first groove 10, the second groove 20, a third groove 30, and a fourth groove 40. Meanwhile, in a PIN photodiode 104, portions corresponding to first to third mesa portions are covered with a resist.

(Second Insulating Film Formation Process)

After the groove or mesa formation process, SiN or SiO₂ are stacked again, by the plasma CVD method, on the film of SiN or SiO₂ stacked in the first insulating film formation process. In this process, the mesa formed in the groove or mesa formation process is covered with a film of SiN or SiO₂. In other words, the n-type semiconductor layer 13, the intrinsic semiconductor layer 14, and the p-type semiconductor layer 15 which have been exposed are covered with the film of SiN or SiO₂ and protected in this process.

(Back Surface Electrode Formation Process)

After the second insulating film formation process, the substrate 12 is turned upside down, and the film of SiN or SiO₂ is brought into contact with a fixed base, thereby fixing the substrate 12. In this process, the SiN or SiO₂ functions as a film. Subsequently, a layer of metal such as AuGe or Ti capable of having an ohmic contact is stacked, by the vapor deposition method or the sputtering method, on the entire surface opposite to the side of the n-type semiconductor layer 13 on the substrate 12 (hereinafter, “the surface opposite to the side of the n-type semiconductor layer 13 on the substrate 12” is simply referred to as “the back surface of the substrate 12”). Thereafter, sintering is carried out to obtain an ohmic characteristic. Moreover, Ti/Au or Au layer is sequentially stacked on the metal layer to form the negative electrode 11. The vapor deposition can be exemplified as a method to stack AuGe, Ti, and Au layers.

(P-Side Electrode Formation Process)

After the back surface electrode formation process, the substrate 12 is removed from the fixed base, and a resist is applied onto the film of SiN or SiO₂ stacked in the second insulating film formation process. Subsequently, an opening corresponding to a portion where the p-side electrode 3 is to be formed is made in the film of SiN or SiO₂ so as to expose the p-type semiconductor layer 15, by the lithography method and the dry etching method as described in the groove or mesa formation process. After the dry etching, the resist is removed. Thereafter, a resist pattern (an opening pattern corresponding to shapes of the p-side electrode 3, the metal wiring 7, and the electrode pad 9) is formed again by the lithography method, and a film of Ti/Au is stacked on the insulating film of SiN or SiO₂ and on the resist pattern by the vapor deposition method. Here, the Ti/Au and the p-type semiconductor layer 15 are brought into contact with each other because the Ti/Au enters the opening portion of the SiN or SiO₂ film. After the Ti/Au film is vapor-deposited, the resist pattern is removed, so that the p-side electrode 3, the metal wiring 7, and the electrode pad 9 are formed.

The PIN photodiode 101 can be manufactured by carrying out the above PIN photodiode manufacturing method. It should be noted that the SiN or SiO₂ films, which are stacked in the first insulating film formation process and the second insulating film formation process, function as the anti-reflection film 17 on the light reception surface 5, and function as the insulating film 16 except on the light reception surface 5.

When light is applied to the PIN photodiode 101, holes and electrons are generated in the intrinsic semiconductor layer 14. However, holes generated in the intrinsic semiconductor layer 14 except below the light reception surface 5 hardly move to the p-side electrode 3 in a direct manner, because the groove 10 functions as a barrier.

Accordingly, most holes reaching the p-side electrode 3 are those generated in the intrinsic semiconductor layer 14 below the light reception surface 5, so that the light response of the PIN photodiode 101 can be improved compared with the conventional PIN photodiode. It should be noted that as long as the depth of the first groove 10 is deeper than the depth of the p-type semiconductor layer 15, it is possible to improve the light response of the PIN photodiode 101.

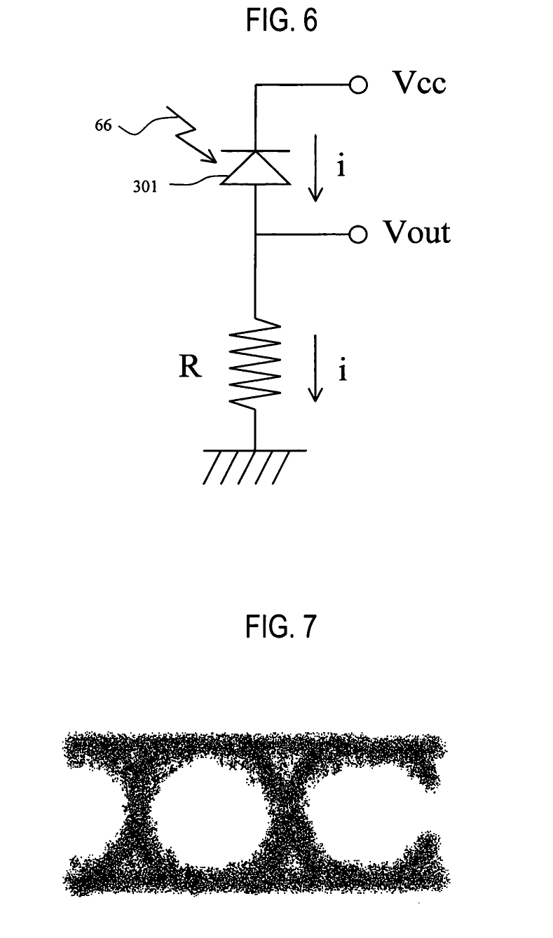

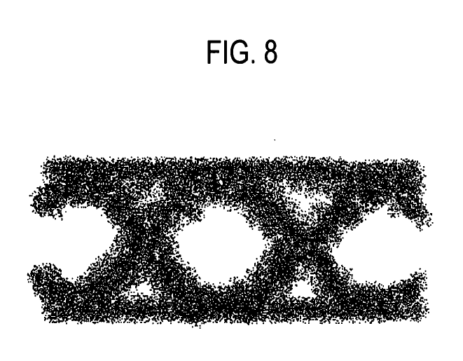

The PIN photodiode 101 was connected in the same manner as a PIN photodiode 301 of FIG. 6 to measure its light response. FIG. 7 shows an eye pattern that is a measurement result of the light response of the PIN photodiode 101. Since the light response of the PIN photodiode 101 is improved, the eye pattern of the PIN photodiode 101 is improved compared with the eye pattern of the conventional PIN photodiode of FIG. 8.

Moreover, since the metal wiring 7 connects the p-side electrode 3 to the electrode pad 9 above the p-type semiconductor layer 15, it is possible to reduce disconnection failure between the p-side electrode 3 and the electrode pad 9.

### Second Embodiment

A PIN photodiode of this embodiment further includes: an electrode pad; and a second groove. The electrode pad is formed at a position different from the certain area surrounded by the first groove on a surface opposite to the substrate. The second groove curves in the longitudinal direction so as to surround a part of an outer circumference of the electrode pad on the surface opposite to the substrate, and extends from the surface opposite to the substrate to have a depth deeper than the intrinsic semiconductor layer in the stacking direction.

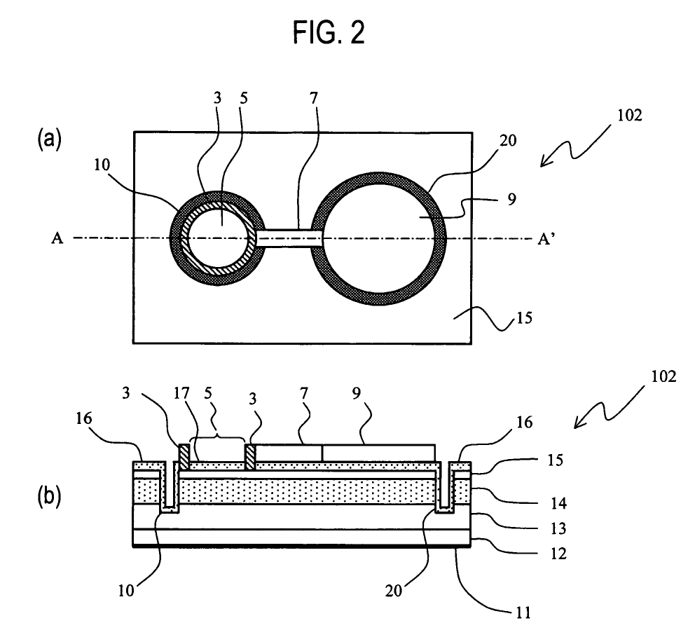

A conceptual diagram of a PIN photodiode 102 according to this embodiment is shown in FIG. 2. The relationship between FIG. 2(a) and FIG. 2(b) is the same as the relationship described in the conceptual diagram of the PIN photodiode 101 of FIG. 1. In FIG. 2, the same reference numerals as in FIG. 1 denote the same semiconductor films and parts, and have the same functions. The PIN photodiode 102 is configured in a similar manner to the PIN photodiode 101 of FIG. 1. The difference between the PIN photodiode 102 and the PIN photodiode 101 is that the PIN photodiode 102 includes a second groove 20 around the electrode pad 9. It should be noted that, in FIG. 2(a), illustrations of the insulating film 16 and the anti-reflection film 17 are omitted in order to describe a structure of the PIN photodiode 102.

The second groove 20 curves in the longitudinal direction so as to surround a part of an outer circumference of the electrode pad 9 on the surface opposite to the substrate 12, and extends from the surface (the insulating film 16) opposite to the substrate 12 to have a depth deeper than the intrinsic semiconductor layer 14 in the stacking direction.

The PIN photodiode 102 is manufactured in the same manner as the PIN photodiode 101 described in FIG. 1.

Accordingly, even when light is applied to the entire surface of the PIN photodiode 102, the light response of the PIN photodiode 102 can be improved compared with the conventional PIN photodiode, as in the description of the PIN photodiode of FIG. 1. It should be noted that as long as the depth of the second groove 20 is deeper than the depth of the intrinsic semiconductor layer 14, it is possible to improve the light response of the PIN photodiode 102.

The PIN photodiode 102 was connected in the same manner as the PIN photodiode 301 of FIG. 6 to measure its light response. As a result of the measurement, almost the same eye pattern as in FIG. 7 was obtained. Since the light response of the PIN photodiode 102 is improved, the eye pattern of the PIN photodiode 102 is improved compared with the eye pattern of the conventional PIN photodiode of FIG. 8.

Moreover, since the metal wiring 7 connects the p-side electrode 3 to the electrode pad 9 above the p-type semiconductor layer 15, it is possible to reduce disconnection failure between the p-side electrode 3 and the electrode pad 9.

### Third Embodiment

A PIN photodiode of this embodiment further includes: a p-side electrode; metal wiring; a third groove; and a fourth groove. The p-side electrode is formed on a surface, opposite to the substrate, of the p-type semiconductor layer in the certain area surrounded by the first groove; at the same time, the p-side electrode is shaped so as to expose a part of the certain area surrounded by the first groove on the surface opposite to the substrate. The metal wiring is formed on the surface opposite to the substrate so as to extend from an area where one end in the longitudinal direction of the first groove faces its other end to an area where one end in the longitudinal direction of the second groove faces its other end; at the same time, the metal wiring electrically connects the p-side electrode to the electrode pad. The third groove extends, on the surface opposite to the substrate, from one end in the longitudinal direction of the first groove to one end in the longitudinal direction of the second groove, along one edge in the longitudinal direction of the metal wiring; at the same time, the third groove extends from the surface opposite to the substrate to have a depth deeper than the intrinsic semiconductor layer in the stacking direction. The fourth groove extends, on the surface opposite to the substrate, from the other end in the longitudinal direction of the first groove to the other end in the longitudinal direction of the second groove, along the other edge in the longitudinal direction of the metal wiring; at the same time, the fourth groove extends from the surface opposite to the substrate to have a depth deeper than the intrinsic semiconductor layer in the stacking direction.

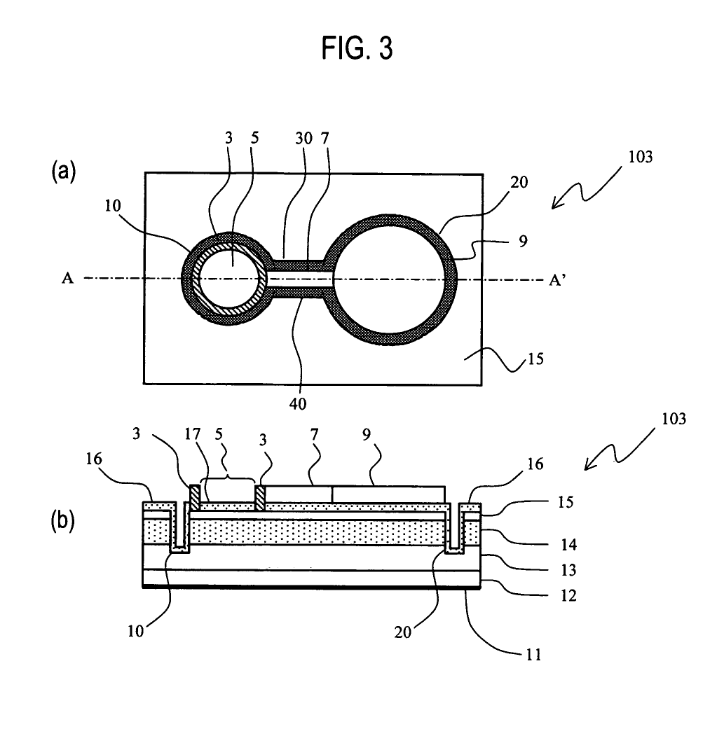

A conceptual diagram of a PIN photodiode 103 according to this embodiment is shown in FIG. 3. The relationship between FIG. 3(a) and FIG. 3(b) is the same as the relationship described in the conceptual diagram of the PIN photodiode 101 of FIG. 1. In FIG. 3, the same reference numerals as in FIG. 1 and FIG. 2 denote the same semiconductor films and parts, and have the same functions. The PIN photodiode 103 is configured in a similar manner to the PIN photodiode 101 of FIG. 1. The difference between the PIN photodiode 103 and the PIN photodiode 102 is that the PIN photodiode 103 includes a third groove 30, and a fourth groove 40 on both edges of the metal wiring 7. It should be noted that, in FIG. 3(a), illustrations of the insulating film 16 and the anti-reflection film 17 are omitted in order to describe a structure of the PIN photodiode 103.

The third groove 30 extends from one end in the longitudinal direction of the first groove 10 to one end in the longitudinal direction of the second groove 20 along one edge in the longitudinal direction of the metal wiring 7, and extends from the insulating film 16 to have a depth deeper than the intrinsic semiconductor layer 14 in the stacking direction.

The third groove 40 extends from the other end in the longitudinal direction of the first groove 10 to the other end in the longitudinal direction of the second groove 20 along the other edge in the longitudinal direction of the metal wiring 7, and extends from the insulating film 16 to have a depth deeper than the intrinsic semiconductor layer 14 in the stacking direction.

The PIN photodiode 103 is manufactured in the same manner as the PIN photodiode 101 described in FIG. 1.

Since the first groove 10, the second groove 20, the third groove 30, and the fourth groove 40 exist in the PIN photodiode 103, portions of the p-type semiconductor layer 15 and the intrinsic semiconductor layer 14 below the light reception surface 5 are completely independent of portions of the p-type semiconductor layer 15 and the intrinsic semiconductor layer not below the light reception surface 5; thus, holes generated in the intrinsic semiconductor layer 14 by light incident on portions except the light reception surface 5 cannot move to the p-side electrode 3.

Accordingly, even when light is applied to the entire surface of the PIN photodiode 103, holes reaching the p-side electrode 3 are only those generated in the intrinsic semiconductor layer 14 below the light reception surface 5, so that the light response of the PIN photodiode 103 can be improved compared with the conventional PIN photodiode. It should be noted that as long as the depths of the third groove 30 and the fourth groove 40 are deeper than the depth of the intrinsic semiconductor layer 14, it is possible to improve the light response of the PIN photodiode 103.

The PIN photodiode 103 was connected in the same manner as the PIN photodiode 301 of FIG. 6 to measure its light response. As a result of the measurement, almost the same eye pattern as in FIG. 7 was obtained. Since the light response of the PIN photodiode 103 is improved, the eye pattern of the PIN photodiode 103 is improved compared with the eye pattern of the conventional PIN photodiode of FIG. 8.

Moreover, since the metal wiring 7 connects the p-side electrode 3 to the electrode pad 9 above the p-type semiconductor layer 15, it is possible to reduce disconnection failure between the p-side electrode 3 and the electrode pad 9.

### Fourth Embodiment

A PIN photodiode of this embodiment includes: a first mesa portion; a second mesa portion; and a third mesa portion. The first mesa portion is composed of: an intrinsic semiconductor layer above a substrate; an n-type semiconductor layer formed on the intrinsic semiconductor layer on the substrate side in the stacking direction; and a p-type semiconductor layer formed on the intrinsic semiconductor layer on the side opposite to the substrate in the stacking direction. The first mesa portion has a mesa extending from a surface, opposite to the substrate, of the p-type semiconductor layer to at least a part of the n-type semiconductor layer, and has, as its top surface, a certain area of the surface, opposite to the substrate, of the p-type semiconductor layer. Also, the first mesa portion has the p-side electrode shaped so as to expose a part of the certain area of the p-type semiconductor layer, and generates electrons and holes in the intrinsic semiconductor layer by light incident from the certain area of the p-type semiconductor layer exposed from the p-side electrode. The second mesa portion includes: the intrinsic semiconductor layer; the n-type semiconductor layer; the p-type semiconductor layer; and an electrode pad formed on the p-type semiconductor layer on the side opposite to the substrate. The second mesa portion has a mesa extending in the stacking direction from the electrode pad to at least a part of the n-type semiconductor layer. The third mesa portion includes: the intrinsic semiconductor layer; the n-type semiconductor layer; the p-type semiconductor layer; and metal wiring formed on the p-type semiconductor layer on the side opposite to the substrate. The third mesa portion has a mesa extending in the stacking direction from the metal wiring to at least a part of the n-type semiconductor layer, and connects the first mesa portion to the second mesa portion. Moreover, the metal wiring of the third mesa portion electrically connects the p-side electrode of the first mesa portion to the electrode pad of the second mesa portion.

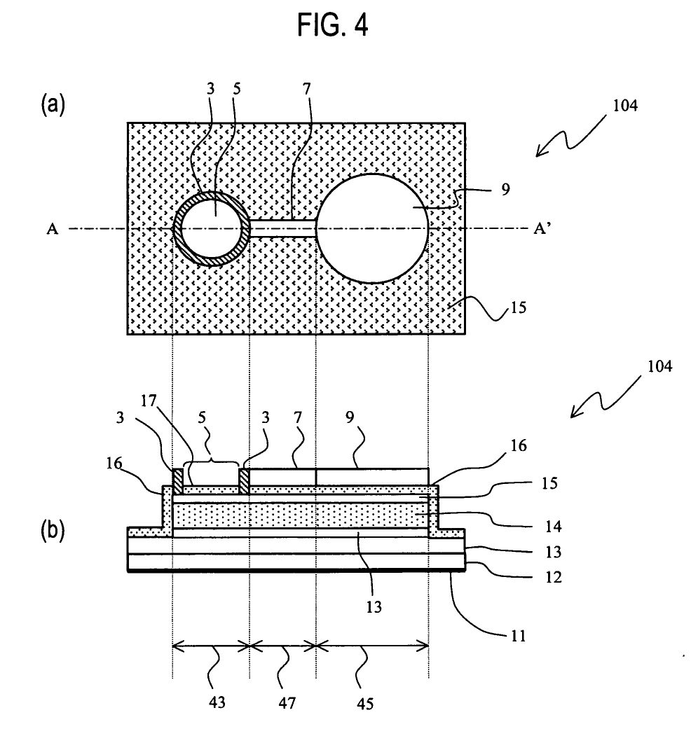

A conceptual diagram of a PIN photodiode 104 according to this embodiment is shown in FIG. 4. The relationship between FIG. 4(a) and FIG. 4(b) is the same as the relationship described in the conceptual diagram of the PIN photodiode 101 of FIG. 1. In FIG. 4, the same reference numerals as in FIG. 1 denote the same semiconductor films and parts, and have the same functions. The PIN photodiode 104 includes: a first mesa portion 43; a second mesa portion 45; and a third mesa portion 47. It should be noted that, in FIG. 4(a), illustrations of the insulating film 16 and the anti-reflection film 17 are omitted in order to describe a structure of the PIN photodiode 104.

The first mesa portion 43 is composed of: the intrinsic semiconductor layer 14 above the substrate 12; the n-type semiconductor layer 13 formed on the intrinsic semiconductor layer 14 on the substrate 12 side in the stacking direction; and the p-type semiconductor layer 15 formed on the intrinsic semiconductor layer 14 on the side opposite to the substrate 12 in the stacking direction. The first mesa portion 43 has a mesa extending from a surface, opposite to the substrate 12, of the p-type semiconductor layer 15 to at least a part of the n-type semiconductor layer 13, and has, as its top surface, a certain area of the surface, opposite to the substrate 12, of the p-type semiconductor layer 15. Also, the first mesa portion 43 has the p-side electrode 3 shaped so as to expose a part of the certain area of the p-type semiconductor layer 15, and generates electrons and holes in the intrinsic semiconductor layer 14 by light incident from the certain area of the p-type semiconductor layer 15 exposed from the p-side electrode 3. Here, the certain area is the light reception surface 5.

The second mesa portion 45 includes: the intrinsic semiconductor layer 14; n-type semiconductor layer 13; the p-type semiconductor layer 15; and the electrode pad 9 formed on the light-reception-side surface. A mesa extends in the stacking direction from the light-reception-side surface to at least a part of the n-type semiconductor layer 13.

The third mesa portion 47 includes: the intrinsic semiconductor layer 14; the n-type semiconductor layer 13; the p-type semiconductor layer 15; the metal wiring 7 formed on the light-reception-side surface. The third mesa portion 47 has a mesa extending in the stacking direction from the light-reception-side surface to at least a part of the n-type semiconductor layer 13, and connects the first mesa portion 43 to the second mesa portion 45. Moreover, the metal wiring 7 of the third mesa portion 47 electrically connects the p-side electrode 3 of the first mesa portion 43 to the electrode pad 9 of the second mesa portion 45.

In other words, the PIN photodiode 104 has an exposed area that is not covered with the p-side electrode 3, the electrode pad 9, or the metal wiring 7; in the exposed area, a portion extending from the p-type semiconductor layer 15 to at least a part of the n-type semiconductor layer 13 is removed. The PIN photodiode 104 can be manufactured in the same manner as the PIN photodiode 101 described in FIG. 1.

In the PIN photodiode 104, the intrinsic semiconductor layer 14 except in the first mesa portion 43, the second mesa portion 45, and the third mesa portion 47 is removed; thus, even when light is applied to the area except the light reception surface 5, holes do not contribute to the output.

Accordingly, even when light is applied to the entire surface of the PIN photodiode 104, holes reaching the p-side electrode 3 are only those generated in the intrinsic semiconductor layer 14 below the light reception surface 5, so that the light response of the PIN photodiode 104 can be improved compared with the conventional PIN photodiode.

The PIN photodiode 104 was connected in the same manner as the PIN photodiode 301 of FIG. 6 to measure its light response. As a result of the measurement, almost the same eye pattern as in FIG. 7 was obtained. Since the light response of the PIN photodiode 104 is improved, the eye pattern of the PIN photodiode 104 is improved compared with the eye pattern of the conventional PIN photodiode of FIG. 8.

In addition, since the first mesa portion 43, the second mesa portion 45, and the third mesa portion 47 have the same height, it is possible to reduce disconnection failure between the p-side electrode 3 and the electrode pad 9.

### Embodiment of Light Reception Device

In this embodiment, provided is a light reception device that includes: anyone of the PIN photodiodes described in the first to fourth embodiments; and a diffuser that diffuses light from the outside, and uniformly applies light to an area including the certain area on a surface opposite to the substrate of the PIN photodiode.

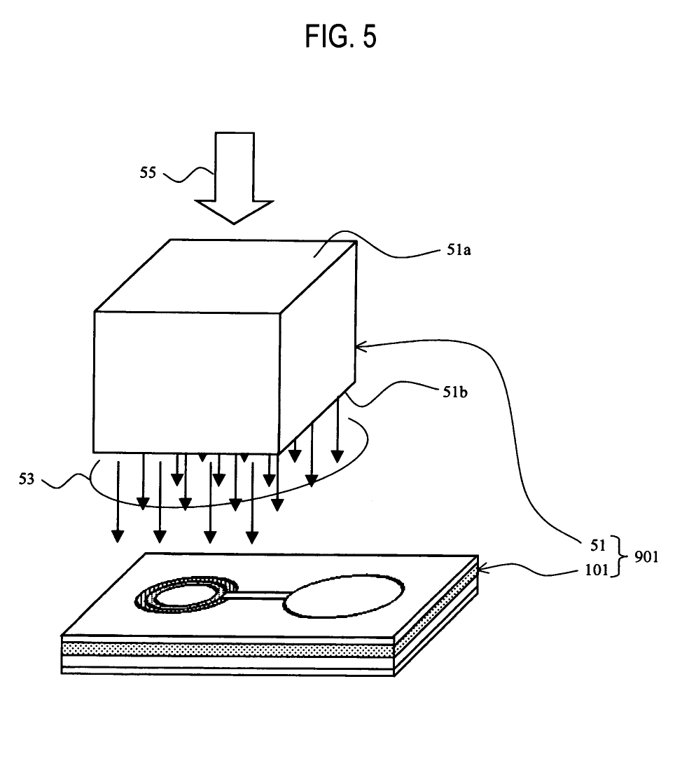

A conceptual diagram of a light reception device 901 according to this embodiment is shown in FIG. 5. The light reception device 901 includes: the PIN photodiode 101 of FIG. 1; and a diffuser 51. It should be noted that a PIN photodiode constituting the light reception device 901 is not limited to the PIN photodiode 101, and the PIN photodiode 102 of FIG. 2, the PIN photodiode 103 of FIG. 3, and the PIN photodiode 104 of FIG. 4 may be employed instead.

The diffuser 51 scatters incoming light 55 incident from an incoming edge 51a, and emits outgoing light 53 having a uniform light intensity distribution from an outgoing edge 51b. It can be exemplified that the diffuser 51 has a configuration as described below.

(Tubular Waveguide)

The diffuser 51 is a tubular waveguide having a mirror on its inner wall. The incoming light 55 incident from the incoming edge 51a repeats specular reflection on the inner wall so as to be emitted with a uniform light intensity from the outgoing edge 51b. Here, there may be employed another configuration in which a refractive index of the inner wall is set lower than that of a region for guiding a light wave. Since the incoming light 55 repeats total reflection on the inner wall, it is possible to obtain the same effect as in a tubular wave guide with a configuration having a mirror on its inner wall.

(Tube With Diffusion Transmission Plate)

The diffuser 51 is a tube having a diffusion transmission plate. The incoming light 55 diffuses while passing through the diffusion transmission plate so that the outgoing light 53 with a uniform light intensity can be emitted from the outgoing edge 51b.

(Tube With Lens Set)

The diffuser 51 is a tube including a lens set having a convex lens and a concave lens combined with each other. The incoming light 55 can have a uniform light intensity distribution while passing through the lens set. For example, a fly-eye lens can be exemplified as the lens set.

The diffuser 51 is positioned so that the outgoing light 53 would be applied to an area including the light reception surface 5 of the PIN photodiode 101, and thus the light reception device 901 is configured. The PIN photodiode 101 can prevent, as described in FIG. 1, degradation of light response even when light is applied to an area except the light reception surface. Thus, it is possible to eliminate the need of highly accurate positioning for the diffuser 51 and the PIN photodiode 101.

Accordingly, in the light reception device 901, since highly accurate positioning is not required, manufacturing is easy, and since the PIN photodiode 101 is used, light response can be improved while disconnection failure of metal wiring is reduced.

Moreover, the diffuser 51 can cause the incoming light 55 to be the outgoing light 53 with a uniform light intensity; thus, in an optical connection with the outside such as an optical fiber, it is possible to eliminate the need of highly accurate positioning for the optical fiber and the light reception device 901.

### INDUSTRIAL APPLICABILITY

The configuration of the PIN photodiode according to the present invention can be used in an electrical device such as a transistor or a diode, as well as in a high-frequency compound semiconductor electrical device, as represented by HEMT.

1. A PIN photodiode comprising:
an intrinsic semiconductor layer above a substrate, and the intrinsic semiconductor layer generates electrons and holes by incident light;
an n-type semiconductor layer being formed on the intrinsic semiconductor layer on the substrate side in a stacking direction, and absorbing electrons generated in the intrinsic semiconductor layer;
a p-type semiconductor layer being formed on the intrinsic semiconductor layer on the side opposite to the substrate in the stacking direction, and absorbing holes generated in the intrinsic semiconductor layer; and
a first groove curving along the longitudinal direction so as to surround a certain area of a surface opposite to the substrate, and extending from the surface opposite to the substrate to have a depth deeper than the intrinsic semiconductor layer in the stacking direction.

2. The PIN photodiode according to claim 1, characterized by further comprising:
an electrode pad being formed at a position different from the certain area surrounded by the first groove on the surface opposite to the substrate; and
a second groove curving along the longitudinal direction so as to surround a part of an outer circumference of the electrode pad on the surface opposite to the substrate, and extending from the surface opposite to the substrate to have a depth deeper than the intrinsic semiconductor layer in the stacking direction.

3. The PIN photodiode according to claim 2, characterized by further comprising:
a p-side electrode being formed on the surface, opposite to the substrate, of the p-type semiconductor layer in the certain area surrounded by the first groove, and being shaped so as to expose a part of the certain area surrounded by the first groove on the surface opposite to the substrate;
metal wiring being formed on the surface opposite to the substrate so as to extend from an area where one end in the longitudinal direction of the first groove faces its other end to an area where one end in the longitudinal direction of the second groove faces its other end, and electrically connecting the p-side electrode to the electrode pad;
a third groove extending, on the surface opposite to the substrate, from one end in the longitudinal direction of the first groove to one end in the longitudinal direction of the second groove, along one edge in the longitudinal direction of the metal wiring, and extending from the surface opposite to the substrate to have a depth deeper than the intrinsic semiconductor layer in the stacking direction; and
a fourth groove extending, on the surface opposite to the substrate, from the other end in the longitudinal direction of the first groove to the other end in the longitudinal direction of the second groove, along the other edge in the longitudinal direction of the metal wiring, and extending from the surface opposite to the substrate to have a depth deeper than the intrinsic semiconductor layer in the stacking direction.

4. A PIN photodiode comprising:
a first mesa portion including:
an intrinsic semiconductor layer above a substrate;
an n-type semiconductor layer formed on the intrinsic semiconductor layer on the substrate side in the stacking direction; and
a p-type semiconductor layer formed on the intrinsic semiconductor layer on the side opposite to the substrate in the stacking direction,
the first mesa portion having a mesa extending from a surface, opposite to the substrate, of the p-type semiconductor layer to at least a part of the n-type semiconductor layer, and having a certain area of the surface, opposite to the substrate, of the p-type semiconductor layer as its top surface,
the first mesa portion having a p-side electrode shaped so as to expose a part of the certain area of the p-type semiconductor layer, and generating electrons and holes in the intrinsic semiconductor layer by incident light from the certain area of the p-type semiconductor layer exposed from the p-side electrode;
a second mesa portion including:
the intrinsic semiconductor layer;
the n-type semiconductor layer;
the p-type semiconductor layer; and
an electrode pad formed on the p-type semiconductor layer on the side opposite to the substrate,
the second mesa portion having a mesa extending in the stacking direction from the electrode pad to at least a part of the n-type semiconductor layer; and
a third mesa portion including:
the intrinsic semiconductor layer;
the n-type semiconductor layer;
the p-type semiconductor layer; and
metal wiring formed on the p-type semiconductor layer on the side opposite to the substrate,
the third mesa portion having a mesa extending in the stacking direction from the metal wiring to at least a part of the n-type semiconductor layer,
the third mesa portion connecting the first mesa portion to the second mesa portion,
the PIN photodiode characterized in that the metal wiring of the third mesa portion electrically connects the p-side electrode of the first mesa portion to the electrode pad of the second mesa portion.

5. A light reception device comprising:
any one of the PIN photodiodes according to claim 4;
a diffuser which diffuses light from the outside and uniformly applies light to an area including the certain area on the surface opposite to the substrate of the PIN photodiode.

6. A light reception device comprising:
any one of the PIN photodiodes according to claim 3;
a diffuser which diffuses light from the outside and uniformly applies light to an area including the certain area on the surface opposite to the substrate of the PIN photodiode.

7. A light reception device comprising:
any one of the PIN photodiodes according to claim 2;
a diffuser which diffuses light from the outside and uniformly applies light to an area including the certain area on the surface opposite to the substrate of the PIN photodiode.

8. A light reception device comprising:
any one of the PIN photodiodes according to claim 1;
a diffuser which diffuses light from the outside and uniformly applies light to an area including the certain area on the surface opposite to the substrate of the PIN photodiode.
